(19) United States
(12) Patent Application Publication
(10) Pub. No.: US 2021/0112670 A1
(43) Pub. Date: Apr. 15, 2021

(54) Flexible LED Modules

(71) Applicant: BeTerrific!!, Corp., Fort Lee, NJ (US)

(72) Inventors: Michael Artsis, Fort Lee, NJ (US); David Milch, Fort Lee, NJ (US)

(73) Assignee: BeTerrific!!, Corp., Fort Lee, NJ (US)

(21) Appl. No.: 17/066,678

(22) Filed: Oct. 9, 2020

Related U.S. Application Data
(60) Provisional application No. 62/914,235, filed on Oct. 11, 2019.

(51) Int. Cl. H05K 5/00; G09G 3/00; G06F 3/14; G09G 3/32; H01L 25/13; H05K 5/02

(52) U.S. Cl. CPC H05K 5/0021; G09G 3/035; G06F 3/1446; G09G 2380/02; H01L 25/13; H05K 5/0017; H05K 5/0217; G09G 3/32

(57) ABSTRACT

The current application discloses systems and methods relating to a lightweight, modular, and flexible LED video display. In accordance with the disclosure, the LED video assemblies may be attached directly to the surface of a frame. The LED video assembly may include a flexible panel that allows the LED display to automatically conform to the curvature of a surface of the frame when attached. For example, the flexible panel may be conformed any of a convex, concave, or flat curvature. The LED video assembly may be attached to the frame without the use of tools and without the use of a complex mechanical locking mechanism.

### CROSS-REFERENCE TO RELATED APPLICATIONS

The present application claims the benefit of the filing date of U.S. Provisional Patent Application No. U.S. 62/914,235 filed Oct. 11, 2019, the disclosure of which is hereby incorporated herein by reference.

### BACKGROUND

Presently, in the field of light emitting diode (LED) display screens, there exists many LED screens that display graphical images. However, while LED screens are able to be combined to display graphical images, these LED screens are bulky, heavy, and difficult to assembly. In particular, these LED screens require a particular support structure that cannot be changed or modified. In addition, given the weight and design of the LED screens, these large support structures are required to be large and to include complex locking mechanisms. These support structures must also be designed to a particular configuration and orientation to accommodate currently available LED screens. Accordingly, the currently available LED screens limit the versatility by which the LED screens can be assembled and arranged.

### BRIEF SUMMARY

The present disclosure provides for an LED video screen assembly that is versatile and easy to assemble. As set forth below, the current disclosure provides for LED modules that are flexible, lightweight, and configured to be easily assembled with various support structures of differing configurations and orientations. For example, the flexible, lightweight LED modules disclosed herein are configured so as to conform to frames having a curved surface, including both convex and concave surfaces. In addition, the disclosed LED modules may be easily assembled to both flat and curved frames without requiring the use of tools to attach the LED modules to the frames.

The present disclosure provides for an LED screen system having an LED screen assembly that may include a flexible panel having a front face and a back face; a plurality of LED's arranged on the front face of the flexible LED panel; wherein one or more attachment mechanisms arranged on the back face of the flexible panel; a circuit assembly connected to the flexible panel, wherein the circuit assembly is arranged relative to the flexible panel so as to allow the front face of the flexible panel to be curved in both a convex and concave direction; and wherein the one or more attachment mechanisms are configured to attach to a surface of a frame, and wherein the flexible panel is configured to conform to the curvature of the surface of the frame.

In accordance with aspects of the disclosure the flexible panel may be configured to be conformable to any of a convex, concave, and flat surface of the frame. In addition, the one or more attachment mechanisms may be one or more magnets and the surface of the frame may be magnetic. The flexible panel may be configured to automatically conform to a surface of a frame have a curvature of 50 degrees in the concave direction or 50 degrees in the convex direction. The flexible panel may be slidably positionable on the surface of the frame.

In accordance with aspects of the disclosure, the LED screen system may further comprise a plurality of LED screen assemblies, wherein the plurality of LED screen assemblies are configured to be positionable on the frame so as to conform to the curvature of the surface of the frame and to display a single image over the plurality of LED screen assemblies. The plurality of LED screen assemblies may be configured so as to be positionable on the frame so as to display the single image without visible gaps between the plurality of LED screen assemblies. The position of the one or more attachment mechanisms of each of the plurality of LED screen assemblies may be adjustable relative to the back face of the flexible panel. In addition the LED screen assembly may be water resistant.

In yet other aspects of the disclosure, the LED system may include a plurality of LED screen assemblies, and a frame having one or more surfaces for attaching to the plurality of LED screen assemblies; wherein one or more of the plurality of LED screen assemblies includes: a flexible panel having a front face and a back face; a plurality of LED's arranged on the front face of the flexible LED panel; one or more attachment mechanisms arranged on the back face of the flexible panel for attaching to the one or more surfaces of the frame; and a circuit assembly for providing power and data signals to the flexible panel; wherein the circuit assembly is physically and electrically connected to the flexible panel, wherein the circuit assembly contains a circuit board that is enclosed within a box, wherein the box is connected to the flexible panel at one or more locations by connectors that extend from the box, and wherein the connectors are configured so that a gap exists between the back face of the flexible panel and a bottom surface of the box so as to allow the flexible panel to be curved in both a convex and concave direction, and wherein the flexible panel is configured to conform to the curvature of the one or more surfaces of the frame.

In accordance with aspects of the disclosure, a method of assembling an LED video screen may include attaching a plurality of LED screen assemblies to a frame using a plurality of attachment mechanisms; connecting the plurality of LED screen assemblies to one another so as to transmit image data to each LED screen assembly in the plurality of LED screen assemblies; providing image data, by one or more processors, to the plurality of LED screen assemblies; and displaying the image data on the plurality of LED screen assemblies; wherein the plurality of attachment mechanisms are configured to attach to a surface of the frame, and wherein the plurality of LED screen assemblies have a flexible LED panel that is configured to conform to the curvature of the surface of the frame.

The method may further include identifying gaps or misalignments in the displayed image; and repositioning one or more of the LED screen assemblies relative to the frame so as to remove the gap or misalignment. The flexible LED panel may be configured to be conformable to any of a convex, concave, and flat surface of the frame. The attachment mechanisms may be one or more magnets and the surface of the frame may be magnetic.

In accordance with disclosed methods, the flexible panel may be configured to automatically conform to a surface of a frame have a curvature of 50 degrees in the concave direction or a 50 degrees in the convex direction. The flexible panel may be slidably positionable on the surface of the frame.

In accordance with the disclosed methods the repositioning of the one or more LED screen assemblies may include adjusting a position of one or more attachment mechanisms, and the frame may be the surface of flat or curved sheet metal, with the attachment mechanisms attaching directly to the surface of the flat or curved sheet metal.

### BRIEF DESCRIPTION OF THE DRAWINGS

FIGS. 1A-1F are various views of an LED video screen assembly in accordance with aspects of the disclosure.

FIGS. 2 and 3 is an LED video screen assembly that includes a frame and a flexible LED panel in accordance with aspects of the disclosure.

FIG. 4 shows LED panels with a convex curvature in accordance with aspects of the disclosure.

FIG. 5 is an LED panel with a concave curvature in accordance with aspects of the disclosure.

FIGS. 6-11 show frames to which LED panels may be attached in accordance with aspects of the disclosure.

FIG. 12 shows LED panels incorporated into a three-dimensional sculpture in accordance with aspects of the disclosure.

FIG. 13 is flexible attachment structure that can be used for attaching a flexible LED panel to a frame in accordance with aspects of the disclosure.

FIG. 14 is a PCB board, cables, and attachment structure in accordance with aspects of the disclosure.

FIG. 15 is the back face of a flexible LED panel in accordance with aspects of the disclosure.

FIG. 16 is a power assembly in accordance with aspects of the disclosure.

FIG. 17 is a flow diagram in accordance with aspects of the disclosure.

FIG. 18 is an LED panel and power assembly in accordance with aspects of the disclosure.

FIG. 19 is a plurality of LED panels arranged in a three-dimensional configuration in accordance with aspects of the disclosure.

FIG. 20 is a flexible PCB board that is a part of the LED panels in accordance with aspects of the disclosure.

### DETAILED DESCRIPTION

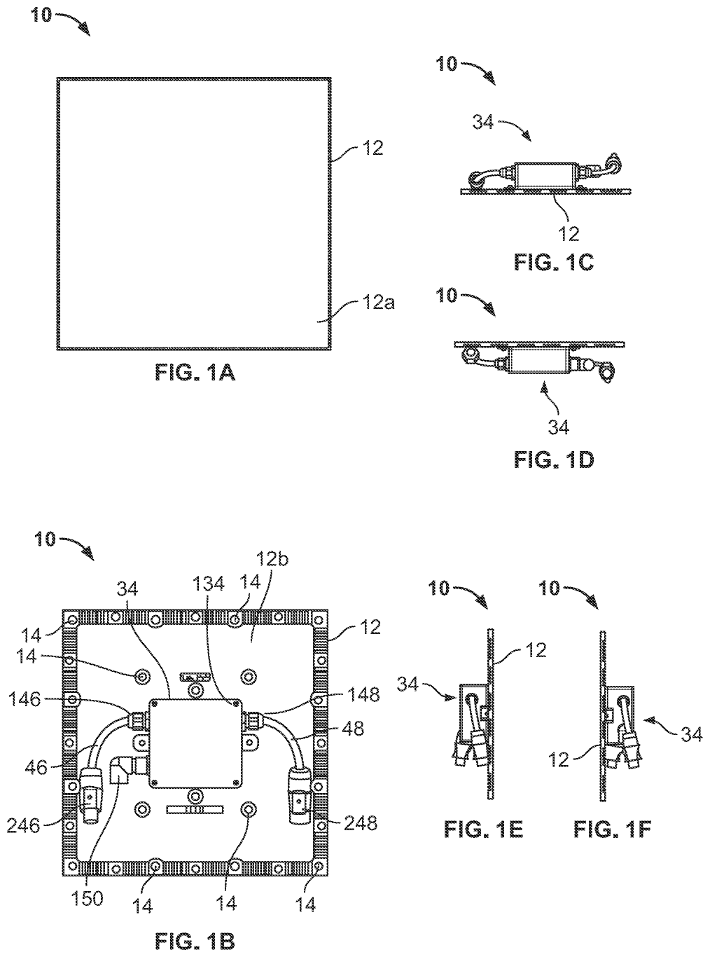

With reference to the figures, wherein like numerals indicate like parts throughout the several views, a light emitting diode (LED) video screen assembly for displaying graphical images is shown in FIGS. 1A-20. The LED video screen assembly 10 may include one LED video screen or a plurality of LED video screens.

An example of an LED video screen assembly 10 can be seen in FIGS. 1A-1F. The LED video screen assembly includes a flexible panel 12 having a front face 12a and a back face 12b. A plurality of LEDs are arranged along the front face 12a of panel 12, so as to form a video screen. On the back face 12b of panel 12 are a plurality of attachment mechanisms 14. These attachment mechanisms 14 are configured to attach panel 12 to a frame assembly, as discussed in more detail below. As shown in FIG. 1B, the attachment mechanisms 14 may be positioned along the periphery of the back face 12b. In addition, some attachment mechanisms may be positioned on an interior portion of the back face 12b. As with other components in the figures provided, only some of the attachment mechanisms 14 are identified with a reference number in FIG. 1B. However, as can be seen in this figure, attachment mechanisms are evenly distributed along the periphery of the back face 12b, including at the four corners of back face 12b. In addition, FIG. 1B shows four attachment mechanisms evenly spaced relative to another on the interior of back face 12b.

As shown in FIGS. 1C-1F, the back face 12b of panel 12 is connected to a power assembly 34. Power assembly 34 may contain circuitry that is capable of receiving data signals and power for the operation of the LED video screen. For example, as shown in FIG. 1B, the LED video screen assembly 10 may receive power from a power cable via the power connector 150. Data signals for operation of the LED video screen may be received by LED video screen assembly 10 via cable 46. In addition, data signals may be output from assembly 10 via cable 48. Cables 46 and 48 are each attached to power assembly 34, respectively, via connectors 146 and 148, which each connect to box 134 that acts as a housing for circuitry of power assembly 34. As will be discussed in further detail below, connector 248 of cable 48 on one LED video screen may be configured to connect with connector 246 of cable 46 on another video screen, so as to pass data from one LED video screen to another. A plurality of LED video screens may then be connected together via cables 46 and 48 of each LED video screen, so as to form an LED video screen assembly 10 that includes any number of LED video screens, and wherein each screen can be provided image data that is specifically designated for that LED video screen.

With regard to the attachment mechanisms 14, in various embodiments, the attachment mechanism 14 allows the panel 12 to be removably attached to a frame. The attachment mechanisms 14 may be chosen from, a male and a female connector, a magnet, Velcro, a screw, a fastener, an interlocking tab fastener, and combinations thereof. Preferably, the attachment mechanisms 14 is one that allows for quick and easy assembly of the LED video screen to a frame. For example, attachment mechanisms 14 in FIG. 1B are magnets have been screwed into the back face 12b of panel 12. These magnet attachment mechanisms 14 can be attached to any magnetic surface of a frame without requiring the use of any tools. In addition, a plurality of attachment mechanisms 14 can be used to couple a first LED video screen assembly 10 to a second LED video screen assembly 10.

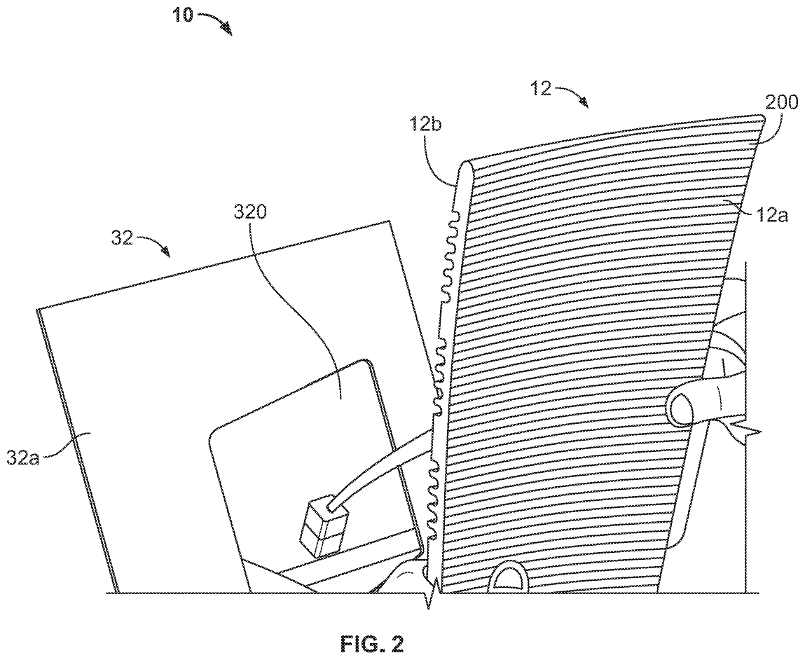

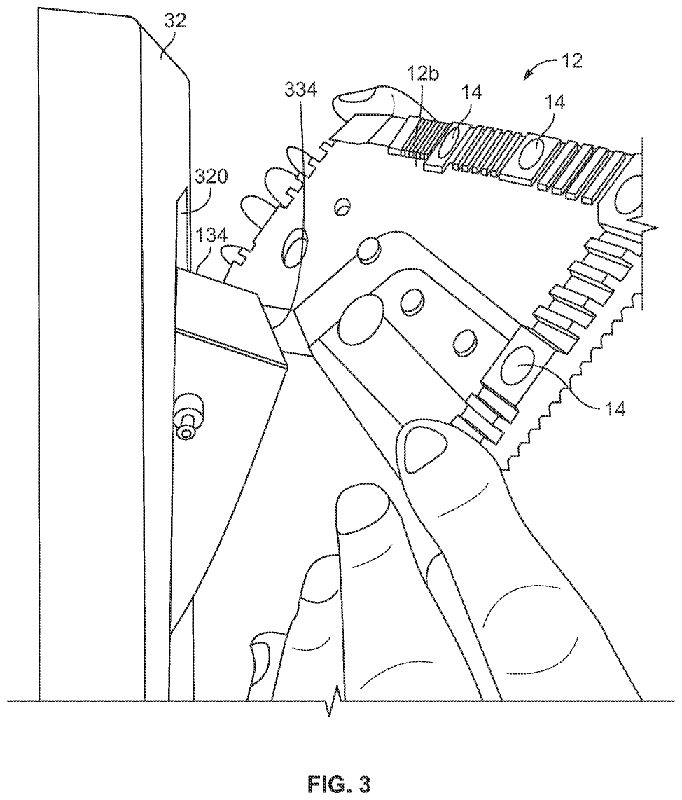

For example, FIG. 2 shows a frame 32 having a front face 32a and an aperture 320. In accordance with aspects of the disclosure, the back face 12b of panel 12 may contain a plurality of magnetic attachment mechanisms that are configured to engage the front face 32a of frame 32 so as to attach panel 12 to frame 32. The configuration of magnetic attachment mechanisms 14 can be seen in FIG. 3. In addition, as shown in FIG. 3, the aperture 320 of frame 32 may be configured so that the box 134 of the power assembly 34 may extend through aperture 320, when panel 12 is attached to frame 32.

Given the configuration of LED video screen assembly 10, each LED video screen can be extremely lightweight, weighing 1-5 pounds per module. These lightweight modules may therefore be held in place on frame 32 by nothing more than the friction between panel 12 and frame 32, which is generated by magnetic attachment mechanisms 14 being attracted to a magnetic surface of frame 32. Thus, LED video screen assembly 10 need not be locked onto frame 32 using tools or complex mechanical locks. Instead, panel 12 may simply be placed onto the front face 32a of frame 32, causing panel 12 to automatically be held in place relative to frame 32. Once flexible panel 12 is placed onto frame 32 it will automatically conform to the surface of front face 32a, so that back face 12b of panel 12 will have substantially the same curvature as front face 32a. In FIG. 2, front face 32a is flat; however as described below, frame 32 may have a variety of non-flat curvatures.

In addition, the attachment mechanisms 14 may be configured so that they are strong enough to prevent movement between the LED video screen and frame 32 due to gravity, but not so strong as to prevent panel 12 from being removed from frame 32 by hand, such as by a person pulling the sides of panel 12 away from front face 32a of frame 32. In this way, single person may quickly and easily assemble and disassemble a plurality of video screen assemblies 10 with a frame 32.

As shown in FIG. 3, panel 12 of LED video screen assembly 10 is configured to be flexible, and may be flexed in more than one direction at once. For example, panel 12 may be constructed of a PCB board with one or more layers of flexible material. Returning to FIG. 2, LEDs 200 on front face 12a of panel 12 may be covered in a layer of clear epoxy (not shown), so as to further secure the LEDs onto panel 12. The epoxy can help hold the LEDs in their mounting locations on panel 12 and prevent LEDs from dislodging from flexible panel 12. An epoxy may also be placed over solder points and other electrical connections on the back of panel 12. The configuration of circuitry within box 134 of power assembly 34, along with the covering of the LEDs and electrical connections with epoxy, allows for LED video screen assembly 10 to be water resistant. Given the features described herein, the LED video screen assemblies 10 are well suited for use on displays that are outside, including displays on moving vehicles, such as cars, planes, etc.

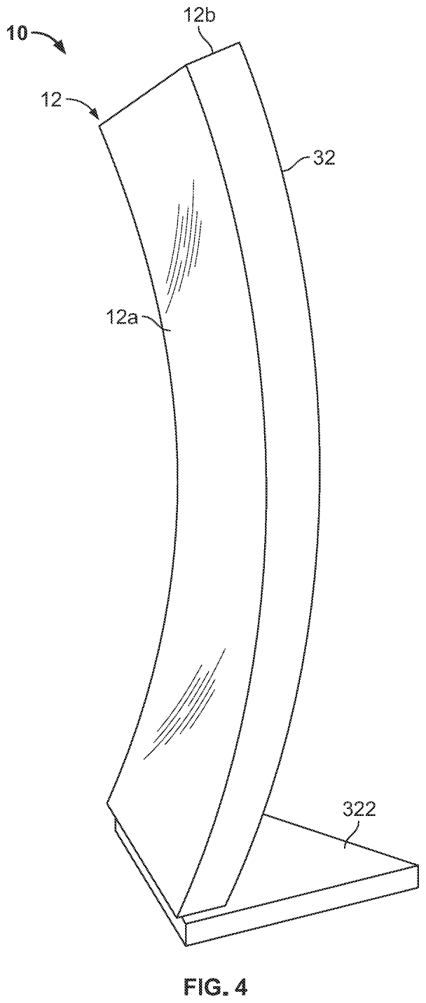

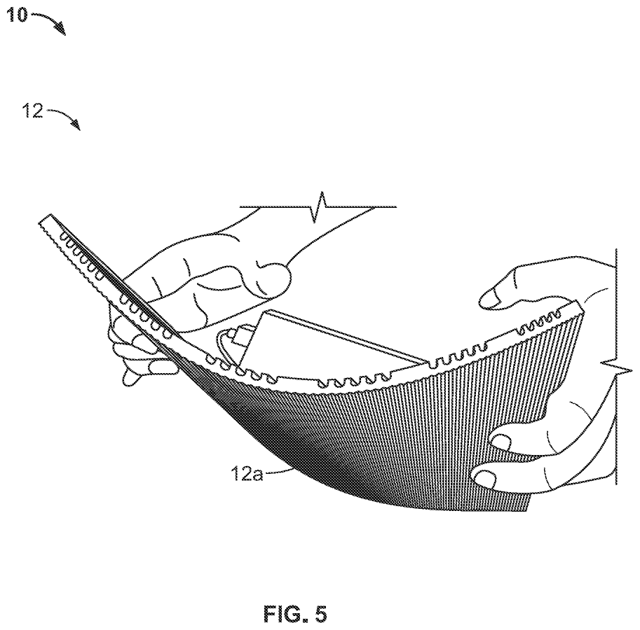

As discussed above, panel 12 of the LED video screen assembly 10 may be made of a flexible material, such as pliable polymers or flexible composite carbon, which is configured as a PCB board onto which LEDs, chips, capacitors, data connections, power connections, and similar components may be attached for operating the plurality of LEDs. The flexibility of panel 12 allows panel 12 to automatically conform to frames of different shapes and configurations. For example FIG. 4 shows a column of a plurality of panels 12 in a LED video screen assembly 10, wherein each panel 12 is conforming to the concave curvature of the front face of frame 32. As discussed above, panel 12 contains attachment mechanisms that allow panel 12 to automatically attach to the front face surface of frame 32. Upon attaching, back face 12b of panel 12 will automatically conform to the curvature of the front face of frame 32. In turn, the front face 12a of panel 12 will also have substantially the same curvature. In this way, the disclosed assembly allows for the creation of a curved display based simply on the curvature of a portion of frame 32. As shown in FIG. 4, frame 32 may be mounted to a base 322 on which the entire assembly may stand.

In addition to the concave curvature shown in FIG. 4, panel 12 may achieve curvatures in a plurality of directions. For example, as shown in FIG. 5, the front face 12a of panel 12 may have a convex curvature. Panel 12 may also be curved in different directions at once. For example, the left and right sides of panel 12 may be flexed back towards the back face of panel 12, while the top and bottom of panel 12 may be flexed forward towards the front face of panel 12, or vice versa. This would produce a panel 12 having a saddle shape, with both convex and concave curvatures. Alternatively, the corners of panel 12 could be brought forward, while the sides of the panel are brought back, or vice versa. This would also create a panel with a saddle shape having both convex and concave curvatures over different regions of panel 12. As described herein, these shapes can be achieved by simply placing panel 12 against a frame 32 that has a front face 32a with the desired curvature, as panel 12 will automatically conform to the curvature of front face 32a.

In accordance with aspects of the disclosure the flexible PCB board of panel 12 may be designed to a desired thickness to achieve the desired flexibility. Preferably, panel 12 is configured so as to not be too floppy and to prevent LEDs from become dislodged when panel 12 is being flexed. For example, panels 12 may achieve convex and concave curvatures that range up to at least 50 degrees of curvature, as determined by the arc of a circle that can be created by panel 12. In other embodiments, the panels may be of a thickness that permits less of a maximum curvature. For example, the PCB board of panel 12 shown in FIGS. 1A-1F are constructed of layers of flexible material so that the overall thickness of panel 12 is about 10 mm and allows for at least 40 degrees of maximum curvature in both the convex and concave directions.

In some embodiments, the position of box 134 of power assembly 34 may prevent panel 12 from achieving the same curvature in the convex direction as the concave direction, as the back face 12b of panel 12 will come into contact with the outer edges of box 134. In certain embodiments, box 134 may be attached to the back face 12b of panel 12 at one or more locations at or near the center of panel 12, with box 134 being connected in a manner so that the box itself is slightly separated from the back face 12b of panel 12. For example, box 134 could be connected via components that extend out from box 134, such as screws or bolts that extend from box 134. The screws or bolts can be configured so that when they are attached to panel 12 there is a gap between the bottom surface of box 134 and back face 12b of panel 12, at least when panel 12 is in a flat configuration, e.g. no convex or concave curvature. This gap may be any desired amount, including about 3 mm. As can be seen in FIG. 3, a gap 334 also exists between box 134 and back face 12b when the front face of panel 12 has a concave curvature. This gap also allows panel 12 to be flexed in a greater angle of convex curvature than if the walls on the periphery of box 134 were directly connected to panel 12. This gap may be adjusted based on the need of convex curvature that is needed for a panel 12 to attach to frame 32.

In various embodiments, two or more LED video screen assemblies 10, of any size and shape, can be connected together to form a larger video display. The two or more video assemblies may be coupled to each other via attachment mechanisms 14 being attached to a common frame 32. When the two or more video wall assemblies are connected together, the edge of the first LED video screen assembly 10 is a predetermined distance from the edge of the second LED video screen assembly. The predetermined distance is also known as the pitch size. The pitch size can be at least, but is not limited to, between 1 mm and 12 mm. In various embodiments, the LED video screen assembly may fit together seamlessly. The LED video screen assembly 10 is of a modular design allowing a plurality of LED video screen assemblies to be built as big as desired. In various embodiments, the plurality of LED video screen assemblies 10 may display one large video image or each LED video screen assembly 10 may display its own individual image that is different than, and independent from, the image or images being displayed by the other LED video screen assembly 10 to which it is connected. The plurality of LED video screen assemblies 10 may be mounted in a curved or flat configuration, as described above. In addition, the plurality of LED video screen assemblies 10 are easily mounted with each other which allows for easy servicing.

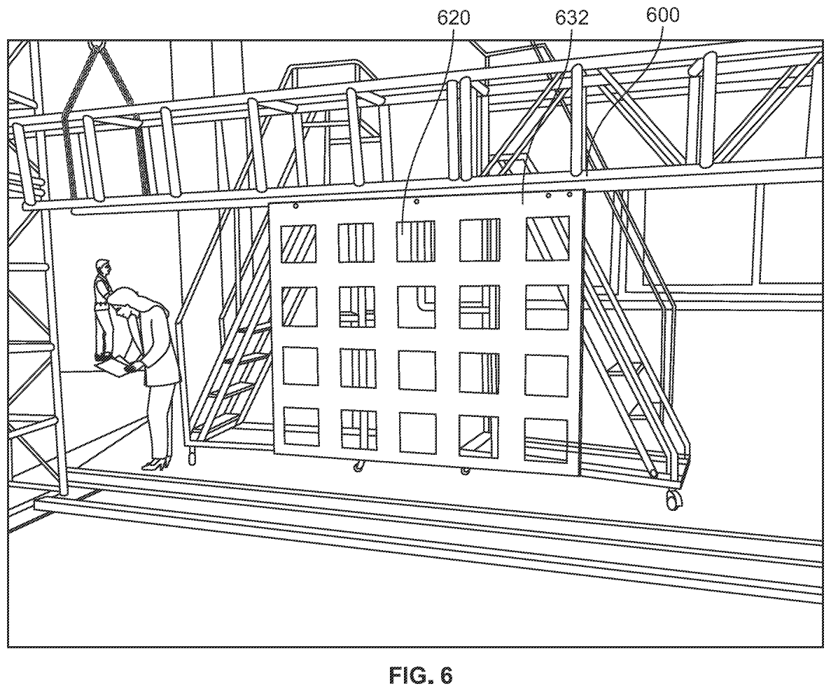

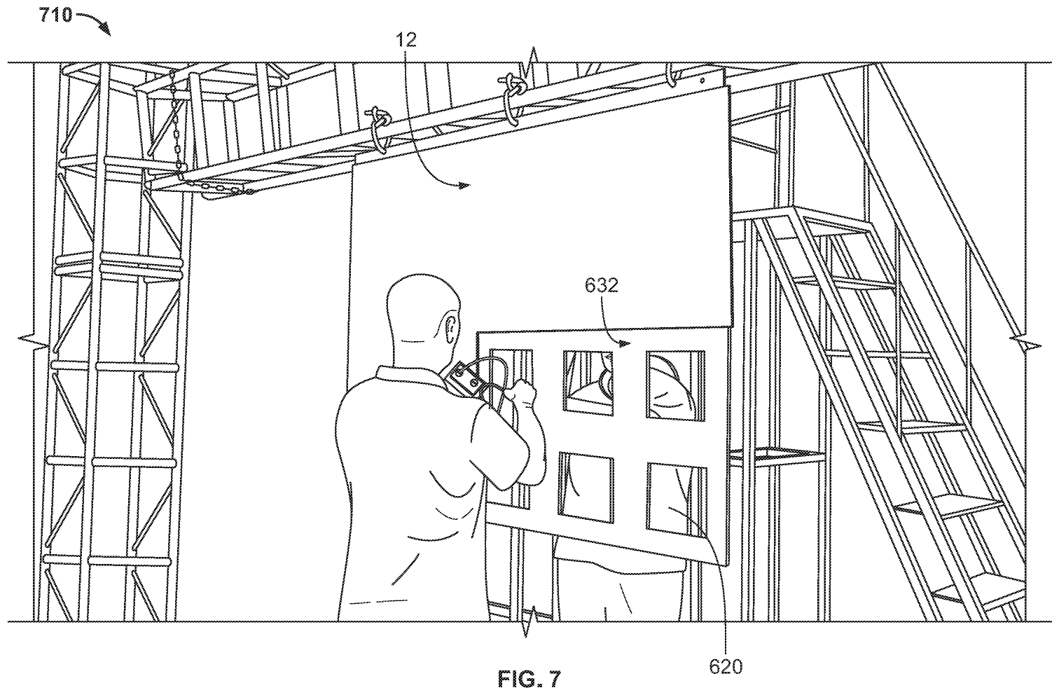

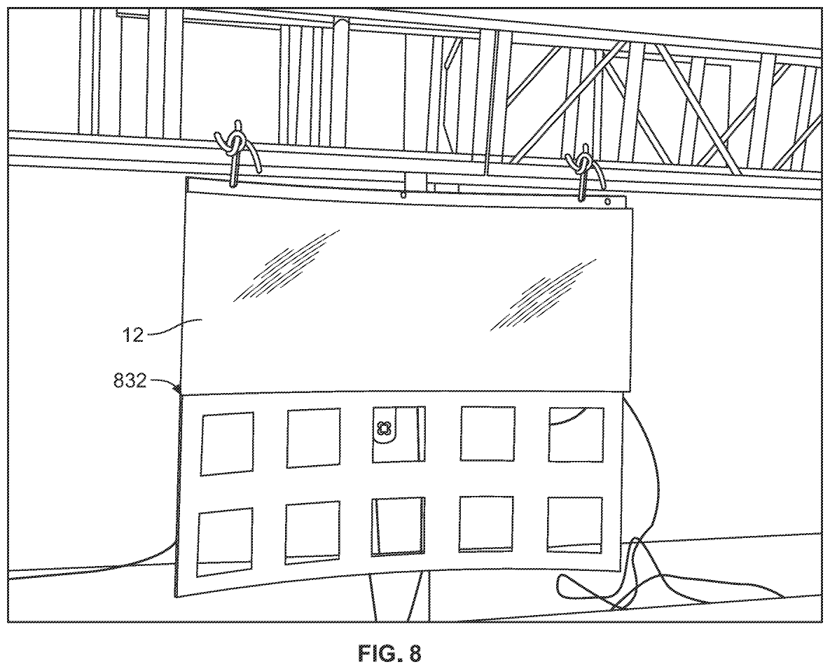

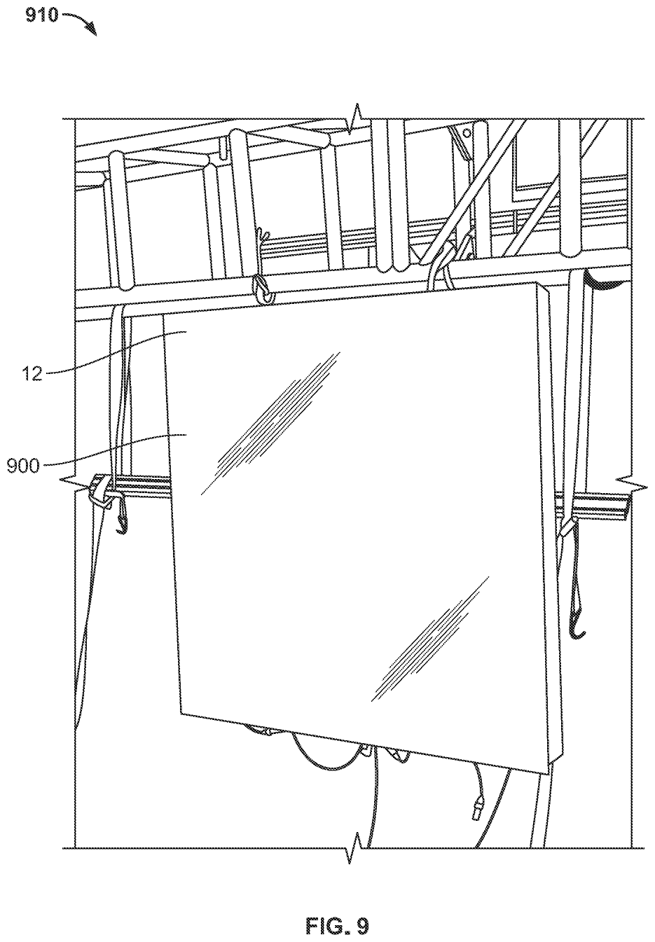

FIG. 6 shows an example of a frame 632 that is suspended by a support structure 600. In accordance with aspects of the disclosure, frame 632 may be a simple piece of sheet metal with one or more apertures 620. As can be seen in FIG. 6, frame 32 contains a grid of apertures that are 5 by 4, so as to allow for a grid of 20 LED panels to be placed onto the frame. FIG. 7 shows an LED video screen assembly 710, wherein frame 632 has a plurality of panels 12 attached to it. In accordance with aspects of the disclosure, the person shown in FIG. 7 may attach a panel 12 over each of the remaining six apertures 620 by simply placing the power assembly that is attached to the back of panel 12 through aperture 620 and allowing the magnetic attaching mechanism attach to the magnetic surface of frame 632. Thus, a display of 20 LED panels 12 may be quickly and easily assembled.

As discussed above, flexible panels 12 are configured so as to conform to the front surface of a frame. As shown in FIG. 8, frame 832 contains a convex curvature on its front face, and panels 12 can be attached to frame 832 so as to automatically conform to substantially the same curvature. Thus, the same LED panels 12 may be used to create a flat display or a curved display in manner that is equally quick and easy to assemble.

FIG. 9 shows a completed LED video screen assembly 910 in which an image 900 is being displayed. As can be seen in FIG. 9, the LEDs of each panel 12 are arranged to extend to each edge of panel 12 so that when a plurality of panels 12 are arranged next to each other, the plurality of panels 12 can display a single image 900 without visible gaps between the panels 12. To the extent the image 900 is misaligned at the location where particular panels meet one another; a person may easily adjust the position of one or more of those panels by simply pulling each panel off and repositioning the panel in a correct position. The misaligned panels may alternatively be repositioned relative to the frame by applying a sufficient force to panel 12 in a desired direction to overcome the friction between panel 12 and the frame, so as to cause panel 12 to be slid into the desired direction.

Returning to FIG. 1B, in one embodiment, the magnetic attachment mechanisms 14 may be adjustably coupled to the back face 12b of panel 12, so that the height of each attachment mechanism 14 from the back face 12b is individually adjustable. These adjustable attachment mechanisms 14 may be used to adjust the height of each panel 12 when it is attached to a particular frame. Thus, each panel 12 on a given frame can be adjusted so that neighboring front faces 12a of neighboring panels 12 are at the same or similar heights, thereby removing any visible gaps between the LEDs on the front face.

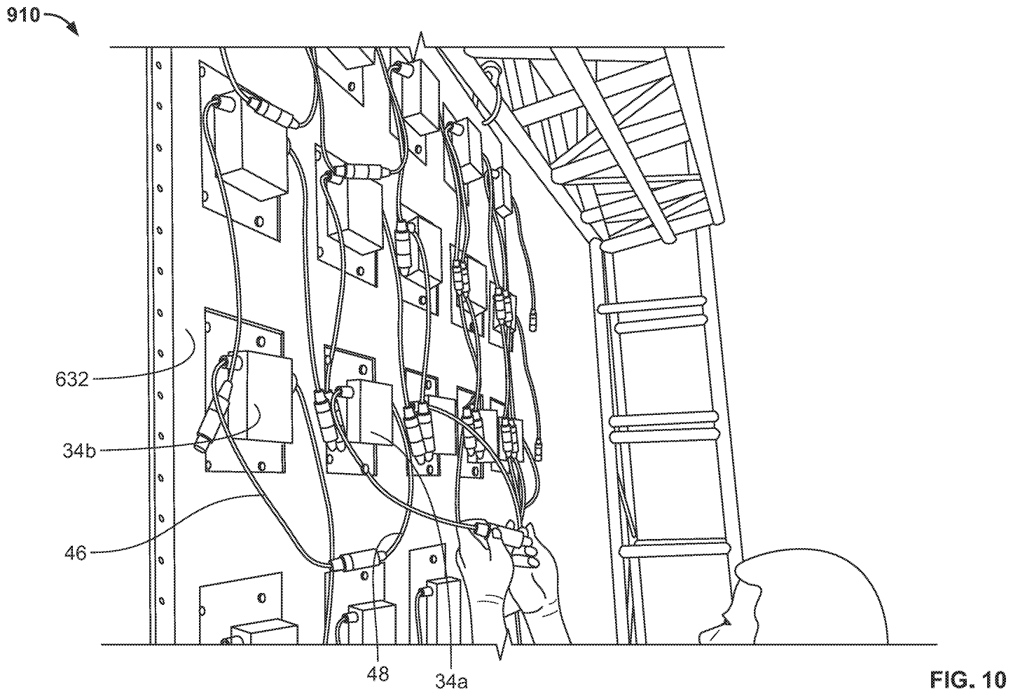

In FIG. 10, the back of LED video screen assembly 910 can be seen, wherein power assemblies 34 extend out from apertures within frame 632. Cable 48 is connected to a data output for power assembly 34a, and cable 46 is connected to a data input for power assembly 34b. Cable 46 and 48 may be connected to one another, thereby allowing data to be transmitted from power assembly 34a to power assembly 34b. The data output cable of power assembly 34b may then be connected to the data input of yet another power assembly in frame 632 so as to continue the data chain until each power assembly 34 has been included in the data chain. The data cables 46 and 48 may include Ethernet cables.

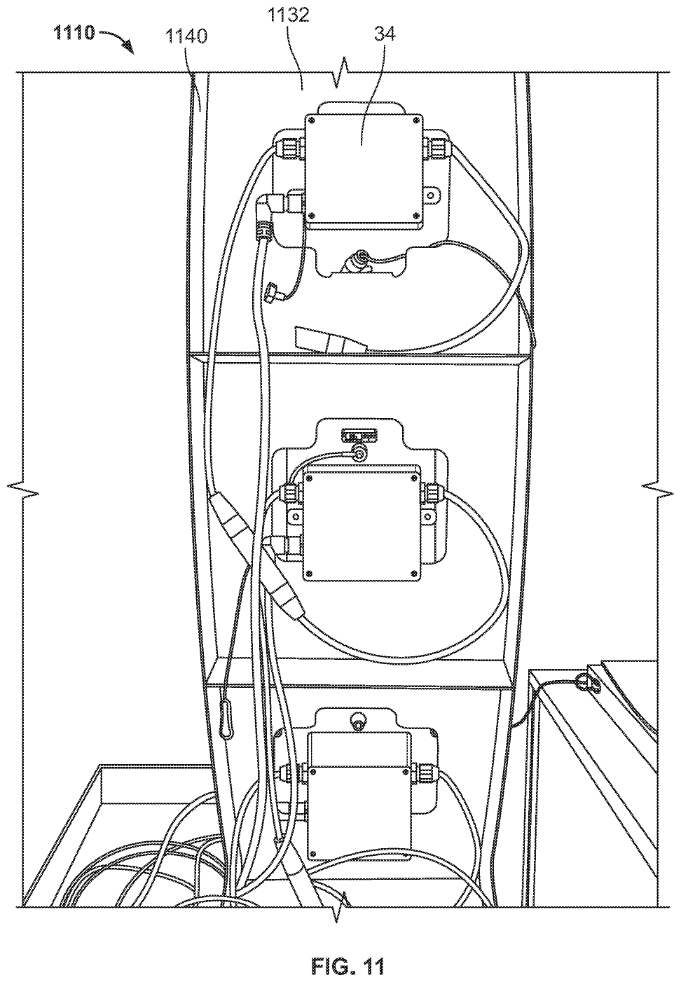

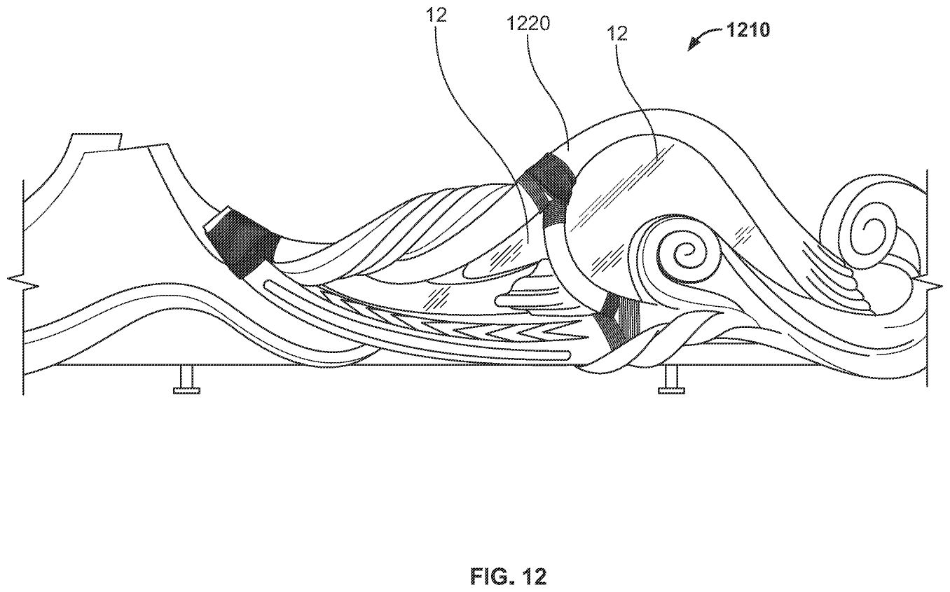

FIG. 11 shows the back of an LED video screen assembly 1110 wherein three LED modules are positioned within frame 1132. As can be seen in FIG. 11, frame 1132 can be configured so that the power assembly 34 of each module is contained within a cabinet 1140. In accordance with aspects of the disclosure, the back of frame 1132 may be covered so as to enclose each power assembly 34 within cabinet 1140.

In FIG. 12, LED video screen assembly 1210 includes a plurality of LED panels 12 that are displaying a video image while incorporated into a sculpture 1220. Given the versatile, water resistant, lightweight, flexible, and modular design of the disclosed LED modules, they may be easily incorporated into various kinds of installations, including sculptures, floats, and other unique structures. As set forth above, the panels 12 may include attachment mechanisms, such as the disclosed array of magnets that allow the LED modules to be installed simply by attaching them to a flat or curved surface, such as a magnetic surface, on the structure. As discussed above, when the flexible panel 12 is installed, it will automatically conform to the curvature of that surface, and the panel can be easily removed or repositioned within the structure without requiring the use of tools or complex locking mechanisms.

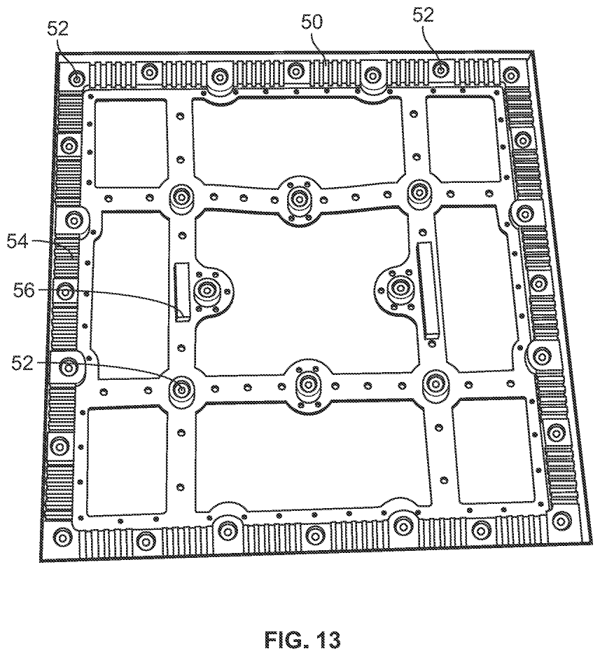

As shown in FIG. 1B, back face 12b of panel 12 may include a plurality of attachment mechanisms 14, such as magnets. In one embodiment, these attachment mechanisms may be attached directly to the PCB board of panel 12. In another embodiment, the attachment mechanisms 14 may be connected to the PCB board of panel 12 via a flexible attachment structure. FIG. 13 shows an example of a flexible attachment structure 50 that can be attached to the back face of the PCB board of panel 12, so as to allow panel 12 to be installed in the manner described above. As shown in FIG. 13, flexible attachment structure 50 forms a grid containing a plurality of attachment sites 52. These attachment sites 52 are configured to receive attachment mechanisms 14 (not shown in FIG. 13), and flexible attachment structure 50 may be configured to extend along substantially all of the back face of a panel 12 (not shown in FIG. 13). The attachment sites 52 may be positioned along the periphery and interior of attachment structure 50, so as to allow for attachment mechanisms to be placed in a manner that will securely hold a flexible LED panel to a frame. As shown in FIG. 13, attachment sites 52 are evenly spaced along the periphery of attachment structure 50, with each side having seven mounting cites. Additional attachment sites are located within the grid pattern 56 on the interior of the attachment structure 50. Attachment structure 50 may also include ridges for engaging the surface of a frame to which a panel is being attached. For example, FIG. 13 shows ridges 54 running along the periphery of attachment mechanism 50.

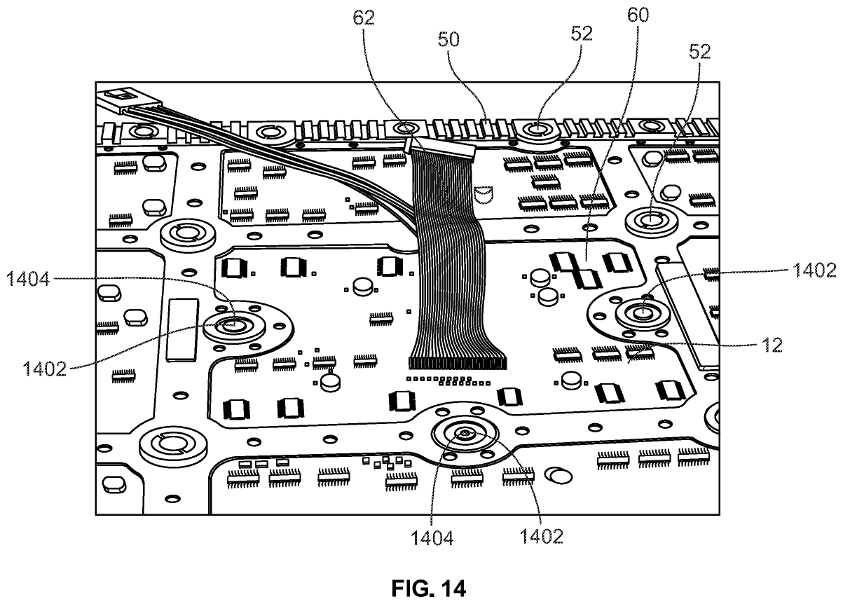

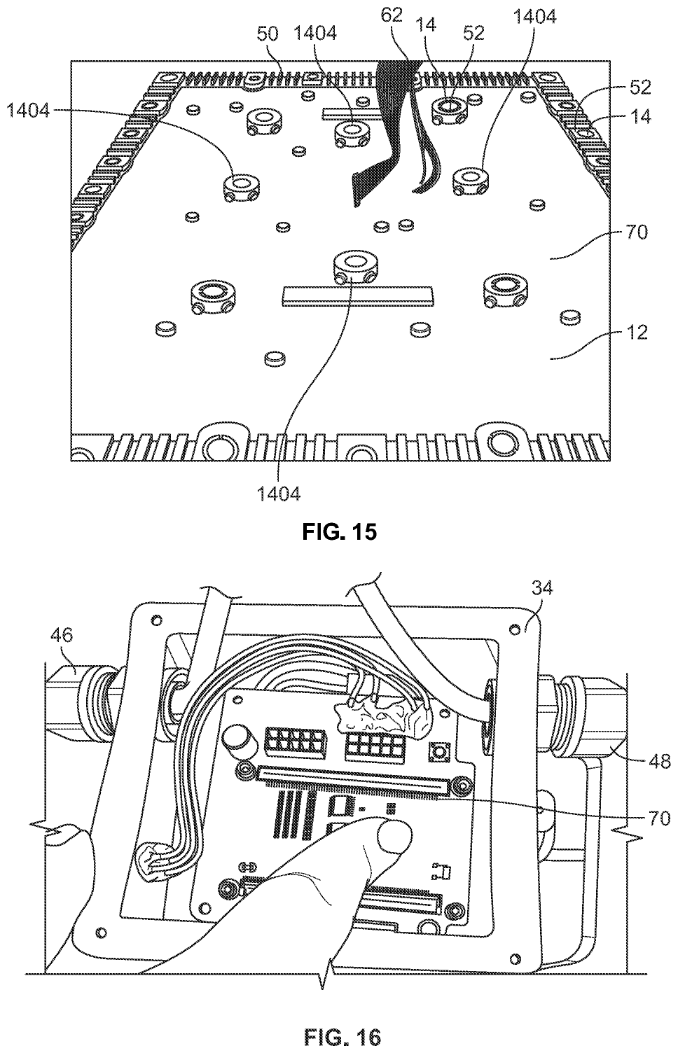

FIGS. 14 and 15 shows an attachment structure 50 attached to PCB board 60 of a panel 12. Attachment structure 50 can be glued to PCB board 60 or may be attached by other means, such as by screwing attachment structure 50 onto PCB board 60. In FIG. 14, attachment structure 50 has been glued onto PCB board 60 using a suitable glue that can sufficiently adhere to rubber and the carbon composite PCB board. In the center of PCB board 60 is a ribbon cable 62, which is configured to be attached to a power assembly 34 (not shown). Attachment structure 50 may also include openings 1402 that allow connection sites 1404 of PCB Board 60 to be exposed. The connection sites 1404 may be used for connecting, such as by screwing or bolting, the box of the power assembly to PCB board 60. In FIG. 15, the attachment structure 50 and PCB board 60 seen in FIG. 14 have been covered with an epoxy 70. Attachment sites 52 remain exposed for coupling to magnetic attachment mechanisms 14 so that panel 12 can be attached to a frame in the manner described above.

Connection sites 1404 also remain exposed so that a power box assembly may be physically connected to panel 12 using screws or bolts. In FIG. 15, four connection sites 1404 are shown. A box for a power assembly may be physically connected to one, two, three, or all four of the connection sites 1404. In one embodiment, a power assembly box may be connected to two opposing connection sites 1404 that sit opposite from one another relative to ribbon cable 62. The choice of which two connection sites 1404, i.e., the vertically aligned pair or the horizontally aligned pair, may be determined based on whether panel 12 will be placed on a frame that requires more curvature in the vertical direction or the horizontal direction. For example, if panel 12 will be attached to a frame that will cause panel 12 to have a greater curvature in the vertical direction, then the power assembly box may be attached to the two connection sites that are aligned in the horizontal direction, so that the box connection will not hinder the panel 12 curvature in the vertical direction.

In one embodiment, a power assembly 34 may be connected to panel 12 by only cables, such as ribbon cable 62. Thus power assembly 34 may be positioned some distance from panel 12, so as to allow panel 12 to freely flex in both the convex and concave directions. In this embodiment, power assembly 34 may be separately attached or stored on the back of frame 32. In this embodiment, aperture 320 of frame 32 may be smaller, as only cables need to pass through them, rather than power assembly box 134.

Power assembly 34 may include a printed circuit board assembly 70, as shown in FIG. 16. The printed circuit board (PCB) assembly 70 may include a 4-layer PCB board that is configured to receive data from cable 46, to output data to cable 48, and to receive power via power connector 150 shown in FIG. 1B. In accordance with one embodiment, PCB assembly 70 may be configured to process more than one data feed and more than one power feed. For example, PCB assembly 70 may receive two data feeds and two power feeds, each of which are received and processed separately by PCB assembly 70. In accordance with this embodiment, PCB assembly 70 may contain two circuit boards, one for controlling a first section of LEDs on the LED video screen and a second board for controlling a second section of LEDs on the LED video screen. Similarly a first power feed and a second power feed may control the first and second sections of LEDs, respectively. Power assembly 34 may also include a receiving card and a HUB for receiving the two data feeds and transmitting the appropriate data feed to each board in the PCB assembly 70. The two data feeds may be provided by separate cables to power assembly 34, or a single cable 46. Similarly the two power feeds may be provided via separate connectors or via a single connector 150.

As set forth above, the LED video screen assembly 10 may include one LED video screen 10 or a plurality of LED video screens 10. As described above, each LED video screen assembly 10 can be connected to another LED video screen assembly 10 via cables 46 and 48. In one embodiment, data output cable 48 may be configured to transmit two data feeds, so that one LED video screen may transmit two data feeds to another LED video screen. In this way, two data feeds are received by each LED video screen, and a panel of multiple LED video screens can be constructed, so as to show either a single video image over multiple panels or multiple independent images over individual panels.

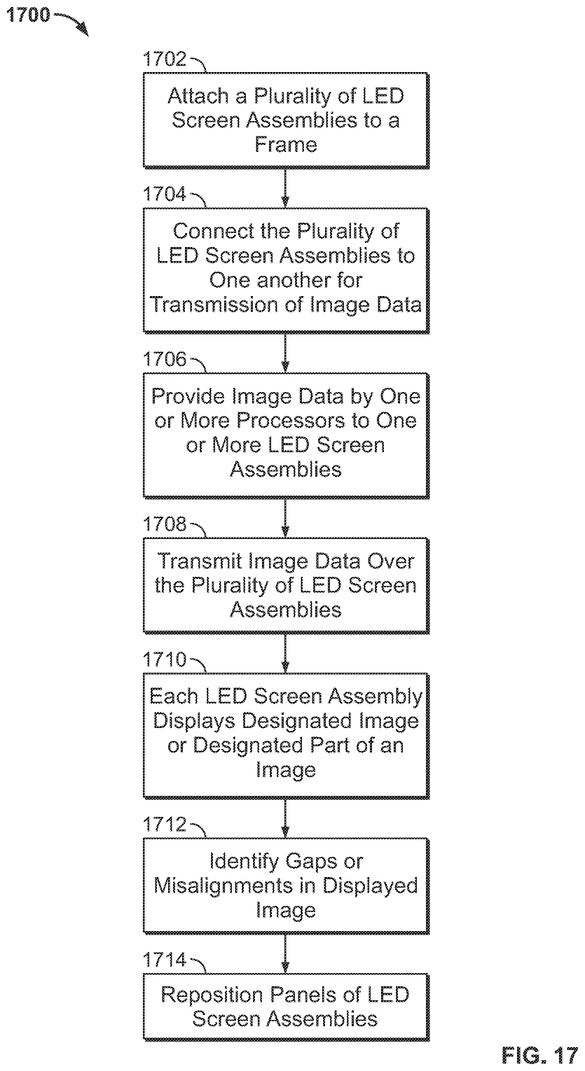

FIG. 17 is a flow diagram 1700 of a method that may be performed in accordance with aspects of the disclosure. Various blocks of flow diagram 1700 may be performed in an order other than that shown in flow diagram 1700, and blocks may be removed or added in accordance with the disclosure provided above. In Block 1702, a plurality of LED screen assemblies 10 are attached to a frame. As discussed above, the LED screen assemblies 10 may contain a flexible panel 12 that is configured to conform to the curvature of a surface of the frame. For example, the frame may have a surface with flat, convex, and/or concave curvatures to which each panel 12 may conform. In Block 1704, the LED screen assemblies are connected to one another for the transmission of image data. For example, as described above, the LED screen assemblies may be daisy chained to one another so that image data may be passed along to each of the LED screen assemblies that are being used. Image data may then be provided to the LED screen assemblies (Block 1706). For example, one or more processors may be used to transmit image data to an LED screen assembly via data input cable 46. This image data may then be transmitted over the plurality LED screen assemblies (1708). In Block 1710, the LED screen assemblies display the designated image, with each LED screen assembly displaying the portion of the image that has been designated for that LED screen. This designation may be included in, for example, an RCGF file that is used by the processor to identify the corresponding location of each LED screen assembly. In Block 1712, any gaps or misalignments in the displayed image may be identified. In accordance with aspects of this disclosure, panels 12 of the LED screen assemblies 10 may be easily repositioned to remove any gaps or misalignments (Block 1714). For example, the locking mechanisms may be configured so as to allow panels 12 to be slidably repositioned along the frame. Alternatively, the locking mechanisms can allow the panel 12 to be easily removed from the frame and placed in a new position or slightly different orientation, without the use of any tools or locking mechanisms. As discussed above, the locking mechanisms can be repositioned on panels 12, such as by adjusting the height of a magnetic attachment mechanism so that the LEDs of neighboring panels align with one another. Thus, the disclosed method allows for easy assembly and quick adjustments of panel orientations and positions.

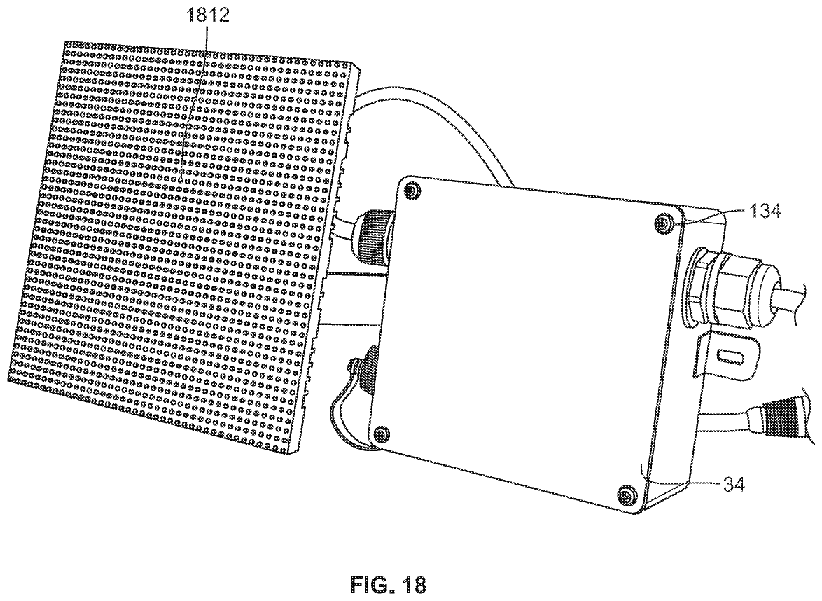

LED video screen assemblies in accordance with the disclosure above may be of many shapes and sizes, e.g. a square, a circle, a rectangle, or any other such shape. In still other embodiments, the LED video screen assembly 10 may be of a shape to fit a unique area or configuration. For example, in some embodiments, the LED video screen assembly 10 may fit the space in which a screen to display graphical images is used. For example, FIG. 18 shows an LED panel 1812 and power assembly 34, wherein the LED panel 1812 is approximately 6 inches by 6 inches square. The height and width of box 134 for power assembly 34 is only slightly smaller than the dimensions of panel 1812. Accordingly, box 134 may be connected to panel 1812 via wires and cables, such as through using ribbon cable 62 described above. The wires and cables connecting power assembly 34 to panel 12 can provide the power and data signals to the PCB board of panel 12 so as to control the display of images on the LEDs of panel 12 in the same manner as described above.

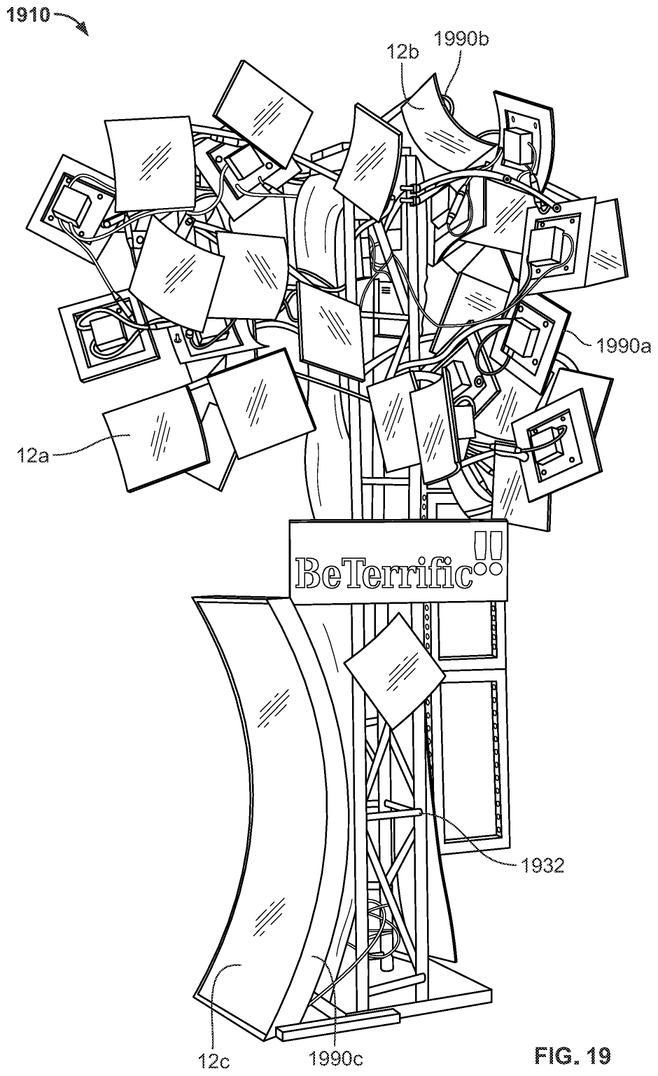

In FIG. 19, an LED video screen assembly 1910 includes a plurality of LED modules attached to a frame structure 1932. As shown in FIG. 19, the panels 12 of each LED module may display a unique image and may have a unique orientation and unique curvature relative to one another. Thus, LED video screen assembly 1910 functions as a three-dimensional LED structure, rather than just a two-dimensional wall of LED panels. The curvature of the panels 12 may be achieved by attaching each panel 12 to a frame backing 1990 that has a particular curvature. For example, frame backing 1990a has a flat curvature, frame backing 1990b has a convex curvature, and frame backing 1990c has concave curvature. As described above, panels 12 are configured to conform to the curvature of each frame backing. Thus panel 12a has a flat curvature, panel 12b has a convex curvature, and panel 12c has a concave curvature.

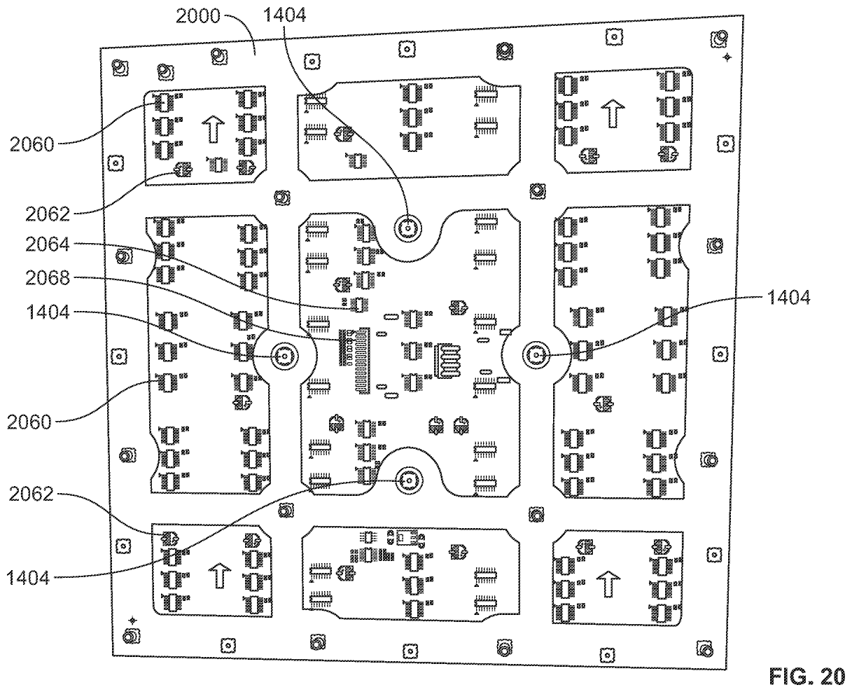

FIG. 20 shows a flexible PCB board 2000 that may be used as part of LED panels 12 described above. PCB board 2000 may be a polymer or composite carbon that is capable of flexing and conforming to the shape of a frame in the manner described above. PCB board may include any electrical connections needed for operation of the plurality of LEDs in displaying any image. For example, PCB board 2000 contains electrical connections 2060 for the connections of driver or processing chips used to control the LEDs that will be connected to the opposite face of PCB board 2000. PCB board 2000 also contains electrical connections 2062 for the connection of capacitors used to regulate the power being provided to the LEDs. Electrical connections 2068 of PCB board 2000 are configured to electrically connect a power assembly 34 (not shown) to the PCB board 2000 at region 2064. As set forth above, the power assembly may provide PCB board 2000 through electrical connections 2068 with power and data signals that are used to control the LEDs for the display of a desired image. As is also discussed above, the box 134 (not shown) for power assembly 34 may be connected to PCB board 2000 via one or more of the connection sites 1404.

In accordance with various embodiments, the frame 32 may be any one of a metal frame, a plastic frame, or a silicon frame. For example, if attachment mechanisms 14 are magnets, a plastic frame 32 may include magnetic attachment sites onto which the magnetic attachment mechanisms 14 may be attached.

In one embodiment, the LED video screen assembly 10 may be water resistant. To improve water resistance, the connection between the power assembly 34 and the panel 12 may be covered with a water resistant material, such as glue or epoxy. In addition, if a copper column is used in connection with the power assembly 34, the flatness of the copper column can be checked to assure a water resistant connection (90° perpendicular to the power assembly 34 (PCBA), whether the copper column is floating or not). If necessary, the copper column of the power assembly 34 can be fixed with 10:1AB glue around it. Water resistance may include testing the light display of panel 12. A check for red, green, and blue LED colors can be performed on the panel 12 so as to check for the phenomenon of dead tin. The method further includes the step of dividing the bottom filling by manually using a syringe to make the IC surface and cool for 5 minutes, light the surface of the panel 12 on the upper machine, and check the lamp surface for glue (if the glue is cleaned in time). Complete the steps to cure, for example, via furnace baking. A lamp board may be fixed into the box 134 of power assembly 34. Before circuitry is placed into box 134, box 134 may be water resistance treated, such as by using a ZT700 treatment agent to coat the surfaces of box 134 for 3-5 minutes. Then the treated box 134 may be placed in flat drip glue on a countertop, such as by using using ZT-508 glue for at least 35 seconds. Next the PCB assembly 70 is inserted into a silicone base of box 134. The power assembly 34 may be filled with glue, with no matte being needed. The glue quantity may be controlled at 45 g+/−1 g. As set forth above, glue may be applied to each of the electrical connections, including the connection of ribbon wire 62 to board 12. The glue that is used may have the following properties:

| Bottom | | Unfilled | IC surface | Total |
|---|---|---|---|---|
| color | | IC face | glue amount | weight |
| white | 38 g | 658 g | 246 g | 931 g |
| black | 45 g | 618 g | 221 g | 839 g |
| black | 47 g | 624 g | 222 g | 846 g |

1. An LED screen system comprising:
an LED screen assembly comprising:
a flexible panel having a front face and a back face;
a plurality of LED's arranged on the front face of the flexible LED panel;
one or more attachment mechanisms arranged on the back face of the flexible panel;
a circuit assembly connected to the flexible panel, wherein the circuit assembly is arranged relative to the flexible panel so as to allow the front face of the flexible panel to be curved in both a convex and concave direction;
wherein the one or more attachment mechanisms are configured to attach to a surface of a frame, and wherein the flexible panel is configured to conform to the curvature of the surface of the frame.

2. The LED screen system of claim 1, wherein the flexible panel is configured to be conformable to any of a convex, concave, and flat surface of the frame.

3. The LED screen system of claim 1, wherein the one or more attachment mechanisms are one or more magnets and wherein the surface of the frame is magnetic.

4. The LED screen system of claim 1, wherein the front face of the flexible panel is configured to have a curvature of up to 50 degrees in the concave direction and 50 degrees in the convex direction.

5. The LED screen system of claim 1, wherein the flexible panel is slidably positionable on the surface of the frame.

6. The LED screen system of claim 1, further comprising a plurality of LED screen assemblies, wherein the plurality of LED screen assemblies are configured to be positionable on the frame so as to conform to the curvature of the surface of the frame and to display a single image over the plurality of LED screen assemblies.

7. The LED screen system of claim 6, wherein the plurality of LED screen assemblies are configured so as to be positionable on the frame so as to display the single image without visible gaps between the plurality of LED screen assemblies.

8. The LED screen system of claim 6, wherein the position of the one or more attachment mechanisms of each of the plurality of LED screen assemblies are adjustable relative to the back face of the flexible panel.

9. The LED screen system of claim 1, wherein the LED screen assembly is water resistant.

10. A method of assembling an LED video screen comprising:
attaching a plurality of LED screen assemblies to a frame using a plurality of attachment mechanisms;
connecting the plurality of LED screen assemblies to one another so as to transmit image data to each LED screen assembly in the plurality of LED screen assemblies;
providing image data, by one or more processors, to the plurality of LED screen assemblies; and
displaying the image data on the plurality of LED screen assemblies;
wherein the plurality of attachment mechanisms are configured to attach to a surface of the frame, and wherein the plurality of LED screen assemblies have a flexible LED panel that is configured to conform to the curvature of the surface of the frame.

11. The method of assembling an LED video screen of claim 10, further comprising:
identifying gaps or misalignments in the displayed image; and
repositioning one or more of the LED screen assemblies relative to the frame so as to remove the gap or misalignment.

12. The method of assembling an LED video screen of claim 10, wherein the flexible LED panel is configured to be conformable to any of a convex, concave, and flat surface of the frame.

13. The method of assembling an LED video screen of claim 10, wherein the attachment mechanisms are one or more magnets and wherein the surface of the frame is magnetic.

14. The method of assembling an LED video screen of claim 10, wherein a front face of the flexible LED panel is configured to have a curvature of up to 50 degrees in the concave direction and 50 degrees in the convex direction.

15. The method of assembling an LED video screen of claim 10, wherein the flexible panel is slidably positionable on the surface of the frame.

16. The method of assembling an LED video screen of claim 11, wherein the repositioning of the one or more LED screen assemblies comprises adjusting a position of one or more attachment mechanisms.

17. The method of assembling an LED video screen of claim 11, wherein the LED screen assemblies are water resistant.

18. The method of assembling an LED video screen of claim 10, wherein the surface of the frame is the surface of sheet metal.

19. The method of assembling an LED video screen of claim 18, wherein the attachment mechanisms attach directly to the surface of the sheet metal.

20. The method of assembling an LED video screen of claim 19, wherein the surface of the sheet metal is curved.

21. An LED screen system comprising:
a plurality of LED screen assemblies; and
a frame having one or more surfaces for attaching to the plurality of LED screen assemblies;
wherein one or more of the plurality of LED screen assemblies comprises:
a flexible panel having a front face and a back face;
a plurality of LED's arranged on the front face of the flexible LED panel;
one or more attachment mechanisms arranged on the back face of the flexible panel for attaching to the one or more surfaces of the frame;
a circuit assembly for providing power and data signals to the flexible panel;
wherein the circuit assembly is physically and electrically connected to the flexible panel, wherein the circuit assembly contains a circuit board that is enclosed within a box, wherein the box is connected to the flexible panel at one or more locations by connectors that extend from the box, and wherein the connectors are configured so that a gap exists between the back face of the flexible panel and a bottom surface of the box so as to allow the flexible panel to be curved in both a convex and concave direction, and wherein the flexible panel is configured to conform to the curvature of the one or more surfaces of the frame.
